(19) United States
(12) Patent Application Publication
(10) Pub. No.: US 2025/0357905 A1
(43) Pub. Date: Nov. 20, 2025

(54) Integrated Circuit Amplifier with Gate Tunneling Resistor

(71) Applicant: Neuralink Corp., Fremont, CA (US)

(72) Inventors: Burak Eminoglu, Fremont, CA (US); SungWon Chung, Fremont, CA (US); Man-Chia Chen, Fremont, CA (US)

(73) Assignee: Neuralink Corp., Fremont, CA (US)

(21) Appl. No.: 18/666,518

(22) Filed: May 16, 2024

(51) Int. Cl. H03F 3/45; H03F 3/187

(52) U.S. Cl. CPC H03F 3/45269; H03F 3/187; H03F 2203/45546; H03F 2203/45602

(57) ABSTRACT

An amplifier circuit with a high pass filter is constructed to include an operational amplifier (op amp) with a feedback loop in which a capacitor is in parallel with a field effect transistor (FET) configured as a gate tunneling resistor. To configure as a gate tunneling resistor, the source and drain of the FET are tied together, and large resistance is provided through the thin oxide layer between the gate and the source/drain. A bias voltage to the FET can be provided through a separate FET, also configured as a gate tunneling resistor. Additional gate tunneling FETs, also in parallel with the capacitor, can be switched into the circuit in order to provide different resistances, and thus different corner frequencies of the filter. Bias voltages may be supplied by one or more gate tunneling FETs. A fully differential op amp can have complementary feedback loops from its differential outputs, each feedback loop employing one or more gate tunneling FETs.

### CROSS-REFERENCES TO RELATED APPLICATIONS

Not applicable.

### STATEMENT AS TO RIGHTS TO INVENTIONS MADE UNDER FEDERALLY SPONSORED RESEARCH AND DEVELOPMENT

Not applicable.

### BACKGROUND

### 1. Field of the Invention

Embodiments of the present invention generally relate to low-frequency amplifiers in integrated circuits employing field-effect devices. Specifically, they relate to amplifiers with high-pass filters utilizing field effect transistors (FET) configured as resistors through gate tunneling.

### 2. Description of the Related Art

A brain-machine interface (BMI), sometimes referred to as a brain-computer interface (BCI), translates neural signals within a brain to electrical signals that can be read by a computing device. Neural signals, miniscule in and of themselves, are surrounded by other neural signals and subject to relatively large-scale common voltage potential changes throughout the day.

It is important to filter out very low frequency noise in neural recording for proper signal acquisition. Filters with very large time-constants are needed for this purpose, which typically require resistors with high resistance.

In order to achieve large resistances in bio-medical applications, pseudo-resistors (PR) are often used. Pseudo resistors conventionally are transistors connected back-to-back, and they are configured such that their currents are forced into the transistors' sub-threshold region. Because they are transistors, pseudo resistors advantageously have compact sizes, which are important for high-channel count systems where many resistors are needed. Unfortunately, because they are operated in the sub-threshold region, pseudo resistors exhibit very large resistance variation across manufacturing process and temperature. In addition, they are extremely sensitive to light, which makes it difficult to perform proper verification and characterization. Lack of proper models of pseudo resistors is another challenge, especially in new designs in new technology nodes.

Regulated pseudo resistors attempt to address the issue of resistance variations. They apply a small voltage to the back-to-back transistor gates, the small voltage being tune to compensate for the variations. However, this comes with the downside of requiring a larger area, higher power, and circuit complexity. Further, there is work in tuning each pseudo-resistor to find optimal voltages.

Other relatively small devices that achieve high resistance, such as duty-cycled resistors and switched capacitor resistors, also require larger area and higher power. These are disadvantages in area-limited applications, such as BCIs.

There is a need in the art for a low-frequency filters for neural recording that are compact, suitable for high-channel counts, and minimally affected by process and temperature variations.

### BRIEF SUMMARY

Generally, an electronic amplifier circuit with a feedback loop is described that includes a capacitor and a field effect transistor (FET) in parallel, the FET configured as a gate tunneling resistor. To configure as a gate tunneling resistor, source and drain terminals of the FET are electrically connected, and current is intended to flow from the gate of the FET, through a very thin (˜2 nm) gate-oxide layer of the FET, to the source/drain terminal or vice versa. The gate tunneling FET can end up having a resistance of greater than 1 giga-ohm (GΩ), especially if a bias voltage bias is applied to keep the gate-to-source/drain voltage near zero. The bias voltage can be applied through another, bias FET that is also configured as a gate tunneling resistor.

The capacitor and FET-resistor in a feedback loop of an operational amplifier (op amp) results in a high pass filter. A large capacitor—along with the relatively high resistivity FET—results in a relatively low cutoff frequency for the high pass filter. Advantageously, the components may be formed by the hundreds, thousands, or millions in an integrated chip. In some cases, the intrinsic capacitance of the FET can be used instead of a separate capacitor.

Multiple FETs configured as gate tunneling resistors may be placed in parallel in the feedback path and switched into the feedback path one-at-a-time. These different “feedback FETs” allow different resistances, and thus different corner frequencies of the high pass filter, to be selected. The selection may be commanded from a user or automatic. Each switched “feedback” FET may be paired with a corresponding bias FET that is also switched and supplies an appropriate bias voltage.

A fully differential operational amplifier circuit can include two feedback loops: one for each differential output running back to a corresponding differential input. For balance, the capacitor capacitances and FET resistances are the generally same between the feedback loops.

As in the single ended op amp version, the fully differential op amp circuit may employ multiple feedback FETs and corresponding bias FETs that may be selected through switches.

Embodiments of the present invention are related to an integrated circuit amplifier apparatus, including an operational amplifier having a voltage input and an output, an AC coupling input capacitor coupled to the voltage input, a feedback capacitor coupled between the output and the voltage input, and a feedback field effect transistor (FET) configured as a gate tunneling resistor in parallel with the feedback capacitor between the output and the voltage input, the FET having a gate, a source, and a drain, wherein configuring the FET as a gate tunneling resistor includes coupling the source and drain together.

The amplifier can include a bias FET configured as a gate tunneling resistor, the bias FET connected between a bias voltage source and the feedback FET. Gates of the feedback FET and the bias FET can be coupled with each other.

The feedback FET can be referred to as a first feedback FET, and the apparatus can further include a second feedback FET configured as a gate tunneling resistor in parallel with the feedback capacitor between the output and the voltage input. It can further include a first bias FET configured as a gate tunneling resistor, the first bias FET connected between a first bias voltage source and the first feedback FET, a second bias FET configured as a gate tunneling resistor, the second bias FET connected between a second bias voltage source and the second feedback FET, and a plurality of pairs of double-throw switches, a switch of each pair connected with one of the bias FETs and another switch of the pair connected with one of the feedback FETs, the switches of each pair configured to mutually toggle. The first and second bias voltage sources can be different or a same voltage source.

The amplifier can include an attenuator or feedback amplifier between the output and the feedback FET. The feedback FET can have a thickness of gate oxide of about 0.8 nanometers (nm) to about 2.2 nm, wherein the thickness enables quantum tunneling current to flow through the gate oxide from a channel beneath the gate oxide. An equivalent resistance of the feedback FET configured as a gate tunneling resistor can be greater than 1 giga-ohm (GΩ). The feedback FET can be a metal oxide field effect transistor (MOSFET).

Some embodiments are related to an integrated circuit amplifier apparatus including a fully differential operational amplifier having differential voltage inputs, a first differential output, and a complementary second differential output. A first feedback capacitor is coupled from the first differential output to one of the inputs, a first feedback field effect transistor (FET) is configured as a gate tunneling resistor in parallel with the first feedback capacitor, a second feedback capacitor is coupled from the second differential output to the other of the differential voltage inputs, the second feedback capacitor having a same capacitance as the first feedback capacitor, and a second feedback FET is configured as a gate tunneling resistor in parallel with the second feedback capacitor.

Each FET can have a gate, a source, and a drain, wherein configuring each FET as a gate tunneling resistor can include coupling the source and the drain within each FET together.

The amplifier can further include a first bias FET configured as a gate tunneling resistor, the first bias FET coupled between a first bias voltage source and the first feedback FET. There can be a second bias FET configured as a gate tunneling resistor, the second bias FET coupled between the first bias voltage source and the second feedback FET.

There can be a third feedback FET configured as a gate tunneling resistor in parallel with the first feedback capacitor, a third bias FET configured as a gate tunneling resistor, the third bias FET coupled between a second bias voltage source and the third feedback FET, and a plurality of pairs of double-throw switches, a switch of each pair coupled with one of the bias FETs and another switch of the pair connected with one of the feedback FETs, the switches of each pair configured to mutually toggle. The amplifier can include a fourth feedback FET configured as a gate tunneling resistor in parallel with the second feedback capacitor, and a fourth bias FET configured as a gate tunneling resistor, the fourth bias FET coupled between the second bias voltage source and the fourth feedback FET. The first and second bias voltage sources can be a different or a same voltage source. A gate side of each feedback FET and a gate side of each bias FET can be connected with one of the differential voltage inputs.

The amplifier can further include an attenuator or feedback amplifier between the first differential output and the first feedback FET. AC coupling input capacitors can be coupled to the differential voltage inputs.

Some embodiments are related to a method of manufacturing an integrated circuit amplifier, the method including providing a fully differential operational amplifier having differential voltage inputs, a first differential output, and a complementary second differential output, coupling a first feedback capacitor from the first differential output to one of the inputs, coupling a first feedback field effect transistor (FET), configured as a gate tunneling resistor, in parallel with the first feedback capacitor, wherein the first FET has a gate, a source, and a drain, the configuring including coupling the gate to one of the differential voltage inputs, and coupling the source and the drain together and to the first differential output, coupling a second feedback capacitor connected from the second differential output to the other of the differential voltage inputs, the second feedback capacitor having a same capacitance as the first feedback capacitor, and coupling a second feedback FET configured as a gate tunneling resistor in parallel with the second feedback capacitor.

The feedback capacitors in the embodiments above can be optional.

Some embodiments are related to an integrated circuit amplifier apparatus including a single-ended or fully-differential operational amplifier having a voltage input and an output, an isolation field effect transistor (FET) configured as a gate tunneling resistor coupled to the voltage input, and a feedback FET configured as a gate tunneling resistor coupled between the output and the voltage input of the op amp. In a fully-differential op amp version, a second isolation FET and feedback FET are connected with the complementary voltage input and output of the op amp.

### BRIEF DESCRIPTION OF THE DRAWINGS

FIG. 1 is a schematic diagram of an amplifier circuit with a single ended op amp in accordance with an embodiment.

FIG. 2 is a schematic diagram of an amplifier circuit with another gate tunneling FET providing a bias voltage in accordance with an embodiment.

FIG. 3 is a schematic diagram of an amplifier circuit with multiple switched feedback FETs in accordance with an embodiment.

FIG. 4 is a schematic diagram of an amplifier circuit with a fully differential op amp and complementary feedback loops in accordance with an embodiment.

FIG. 5 is an upper half of a schematic diagram of a fully differential op amp with multiple switched feedback FETs in accordance with an embodiment.

FIG. 6 is a schematic diagram of an amplifier circuit without any separate feedback capacitors in accordance with an embodiment.

FIG. 7 is a flowchart in accordance with an embodiment.

### DETAILED DESCRIPTION

A compact amplifier with a high pass filter having a very low corner frequency is enabled by using a field effect transistor (FET) configured as a gate tunneling resistor. The low corner frequency allows the inhibition of voltage fluctuations with very low frequencies, on the order of a thousand Hertz (Hz) or lower. The gate tunneling FET offers high resistance for relatively compact real estate on an integrated circuit.

In a metal-oxide-semiconductor field effect transistor (MOSFET), current is intended to flow between a source and a drain in a precisely defined channel. The current is controlled by voltage at a gate. Oxidized silicon, referred to as the “gate oxide,” acts as an insulator to prevent charge carriers in the channel, which is underneath the gate oxide, from traveling to the conductive gate above. However, when the gate oxide of a MOSFET device is very thin, on the order of less than about 2 nanometers (nm), a phenomenon known as “quantum tunneling” becomes prevalent. Quantum effects make probable that an electron or hole make a “quantum jump” across the insulating barrier and appearing in the gate. As complementary metal-oxide-semiconductor (CMOS) technology has achieved smaller and smaller thicknesses, gate currents on the order of femto-amps have been known to flow due purely to quantum tunneling current. It is well studied, and the currents are quite predictable.

Gate tunneling is commonly thought to be a limitation of advanced technology nodes with very thin gate-oxide layers. When electrons tunnel through this narrow layer in normal circuits, they cause unwanted leakage. The leakage increases power dissipation, which is typically a concern in complex digital circuits. Besides in digital circuits, gate tunneling is also known to cause performance degradation in analog and mixed-signal circuits.

However, the phenomenon of gate tunneling in FETs can be harnessed to design a compact resistor with exceptionally high resistance. The gate-oxide leakage can provide a high-resistance, somewhat linear, and well-characterized path, effectively become a high-Ohm resistor. This was found to be exceptionally effective in amplifier circuits for neural recording.

A “gate tunneling resistor” includes a field effect transistor whose source and drain are electrically connected together and whose input and output are designed so that current is intended to travel between the joint source/drain and the gate to exploits the relatively high resistance through the gate oxide layer. The FETs for gate tunneling resistors can have gate oxide thicknesses less than about 2 nanometers, or as otherwise known in the art to enable measurable quantum tunneling currents.

Technical advantages of using gate tunneling in this way include a small form factor with an almost-zero power consumption. Furthermore, it is possible to minimize the FET's light sensitivity by eliminating the diffusion areas. This design avoids the temperature sensitivity of pseudo resistors in favor or quantum tunneling, which is very robust to temperature variations. Further quantum tunneling is well-modeled, especially for typical bias conditions.

### Proposed Architecture for Neural Electrodes

Differential amplifiers are often preferred for low-noise applications due to their superior common mode-rejection ratio (CMRR) and supply-rejection ratio (SRR). They can also, importantly, limit the signal bandwidth before digitization in order to relax the signal-to-noise (SNR) requirements of any subsequent analog-to-digital converter (ADC).

Traditionally, filters are implemented in the feedback path of differential amplifiers using large resistors. Physically large resistors, however, are not feasible for the requirement of extremely low frequencies going below 1 kHz in conjunction with a small form factor. As discussed supra, pseudo resistors are one possible solution; however, they exhibit excessive process, temperature, and light sensitivity. In addition, the lack of proper models make it difficult to estimate pseudo resistor behavior without post-silicon characterization.

Embodiments for neural electrodes use the gate tunneling in a differential amplifier's feedback path in which the sensitive node is only the transistor gates. Hence, there is no diffusion connection. Rather, the diffusion connection between the source and drain is shorted. This minimizes the impact of temperature and light on the system performance.

While quantum tunneling is relatively insensitive to temperature, it does have bias dependency due to its inherent non-linearity. To alleviate this limitation, another quantum tunneling device can be implemented to bias the gate to achieve a reasonable conductance and linearity.

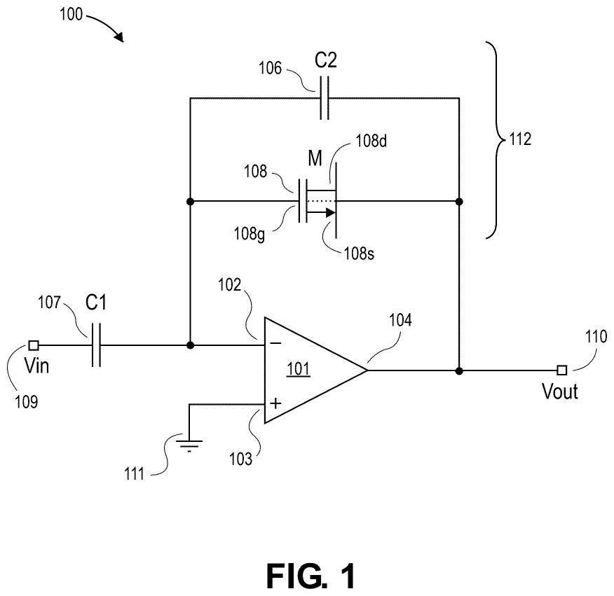

FIG. 1 is a schematic diagram of an amplifier circuit with a single ended op amp. In circuit 100, single-ended op amp 101 has primary voltage input 102 and a complementary voltage input 103. Complementary voltage input 103 is tied to ground. Thus, in this example a signal source that drives the op amp is referenced to ground.

A signal source is applied as input voltage 109, labeled Vin, and enters the circuit through AC coupling input capacitor 107, labeled C1. The input capacitor subtracts any direct current (DC) from alternating currents (AC). The AC signal through the capacitor is fed to primary voltage input 102 of op amp 101. The signal is amplified within op amp 101 and yielded at output 104, which shares the same voltage as output voltage 110, labeled Vout.

Feedback loop 112 takes output 104 of op amp 101 through a parallel path of a capacitor and a field effect transistor (FET) configured as a gate tunneling resistor. Feedback capacitor 106, labeled C2, is in parallel with FET 108, labeled M. FET 108 is a metal-oxide-semiconductor field effect transistor (MOSFET), and it is shown as a p-type, arrow pointing outward. An N-type FET can be used as well.

FET 108 has gate 108g, source 108s, and drain 108d. To configure the FET as a gate tunneling resistor, source 108s and drain 108d are electrically tied/coupled together so that they share a same voltage. Gate 108g serves as one terminal (i.e., an input or an output) of the gate tunneling resistor, and joint source 108s/drain 108d serve as another terminal (i.e., an input or an output). Current is intended to pass between gate 108g and the joint source 108s/drain 108d, preferably at an operating point that makes current linearly related to voltage. With thin gate oxide layers, resistance can be greater than 1 giga-ohm (GΩ), often greater than 10 GΩ.

In an alternate embodiment, the intrinsic capacitance of the gate tunneling FET is harnessed such that no separate capacitor is necessary in the feedback loop.

For this embodiment, the ideal alternating current (AC) response, assuming loop gain is high enough, is:

$$H ( s ) = - \frac{C 1}{C {2}^{*}} \cdot \frac{1}{\frac{1}{{sr}_{gt} C {2}^{*}} + 1}$$

where C2*=C2+C_{gt}, which is the sum of the capacitances of the C2 capacitor and the gate capacitance of the FET (i.e., MOSCAP capacitance), and r_{gt} is the linearized tunneling resistor. From this transfer function equation, it is evident that this circuit is a high-pass filter with a cut-off frequency of:

$${ω}_{c} = \frac{1}{{r}_{gt} C {2}^{*}}$$

FET resistance r_{gt} and capacitance c_{gt} are technology-related parameters that are functions of the FET's direct current (DC) operating point. The DC operating point can be manipulated to optimize resistance and circuit robustness.

In some embodiments, multiple feedback FETs can be placed in series within the feedback path to achieve a desired total resistance. The multiple feedback FETs can be placed in the same orientation, such that all of their gates face toward the voltage input of the op amp and source/drains face toward its output. Or, all of their gates can face toward the output of the op amp and source/drains face toward its voltage input. In some embodiments, the multiple feedback FETs in series are not placed in the same orientation. For example, they may be placed such that their source/drains face each other, their gates face each other, or they are staggered in some other fashion.

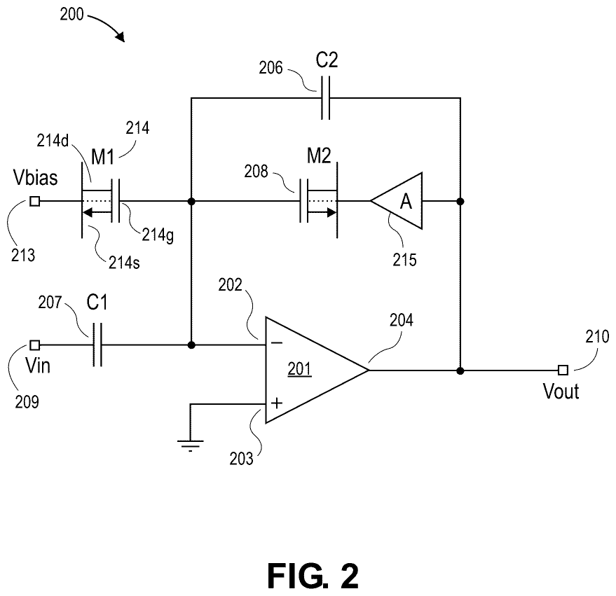

FIG. 2 is a schematic diagram of an amplifier circuit with a second gate tunneling FET that provides a bias voltage to the first FET.

In circuit 200, single-ended op amp 201 has voltage input 202 and output 204. Complementary voltage input 203 is grounded. Signal voltage 209, which is measured from ground, is input through input capacitor 207, labeled C1. At the output of op amp 201 is output 204, which is coupled to output voltage 210, labeled Vout.

A feedback loop includes capacitor 206, labeled C2, in parallel with FET 208, labeled M2, configured for gate tunneling. While quantum tunneling from the gate is relatively insensitive to temperature, it has bias dependency due to its inherent non-linearity. To alleviate this limitation, introduced is another quantum tunneling device to bias the FET's gate to achieve a reasonable conductance and linearity.

FET 214, labeled M1, is configured as a gate tunneling resistor. It is used to bias the gate of M2 from bias voltage 213, labeled Vbias. FET 214 includes gate 214g, source 214s, and drain 214d. Source 214s and drain 214d are directly connected. Electrical current is meant to flow from Vbias through source 214s/drain 214s to gate 214g and on to the gate of M2.

The gate of M1 “looks at” op amp input 202 as well as the gate of M2. That is, the gate of M1 is directly connected to the op amp input and the gate of M2. While this is not critical, there are subtle advantages not detailed here.

Field effect transistors as resistors exhibit significant nonlinearity, which can cause performance degradation. Although the additional transistor for biasing increases complexity, biasing M2's gate helps keep M2 within a linear region and the greater high pass filter well characterized.

While proper biasing would be good enough to ensure linearity, additional modifications can be employed.

Attenuator 215 is provided between output 204 of op amp 201 and the source/drain of FET 208 (i.e., M2). Attenuator 215 can boost the effective resistance of the FET and also decouples the amplifier common-mode biasing and resistor biasing.

It can be important to make sure that the attenuator does not load the core amplifier. Active attenuation can also be implemented, which has a power trade-off. One or more attenuators can also be used for level shifting to decouple output amplifier common-mode voltages and gate tunneling resistor biasing.

Instead of an attenuator (i.e., having a gain less than 1), in some embodiments a feedback amplifier (i.e., having a gain greater than 1) can be employed between the output of the op amp and the feedback FET. A feedback amplifier can reduce the effective resistance of the feedback loop instead of boosting it with an attenuator. This can be desirable in cases where a very small FET is used with very high resistance.

Although quantum tunneling does not necessarily have significant process dependency, it can be important to have tunability-especially for application requiring precision control in the AC characteristics. In addition, programmability is often needed to configure the filters for different application. For the example of neural recording, while the local field application (LFP) bandwidth starts from a few Hz, the neural spike bandwidth starts from about 200 Hz and up.

Conventionally, tunability of filters would be accomplished through switches that have diffusion contacts in the feedback terminal of the amplifier. The downside of this approach is that it would add parasitic paths to the substrate, potentially increasing the light and temperature sensitivity of components and hence changing the substrate's DC offset. Overall, the approach may potentially cause signal range and functionality problems as well as affect the filter characteristics.

Here, a different approach is used in which the nonlinearity of tunneling devices is employed. Much of it centers on the fact that the resistance of a FET configured as a gate tunneling resistor significantly increases if its voltage bias is zero. When the bias voltage across the FET is zero, the resistivity significantly increases. Those FETs not in the signal paths do not play a role in AC characteristics.

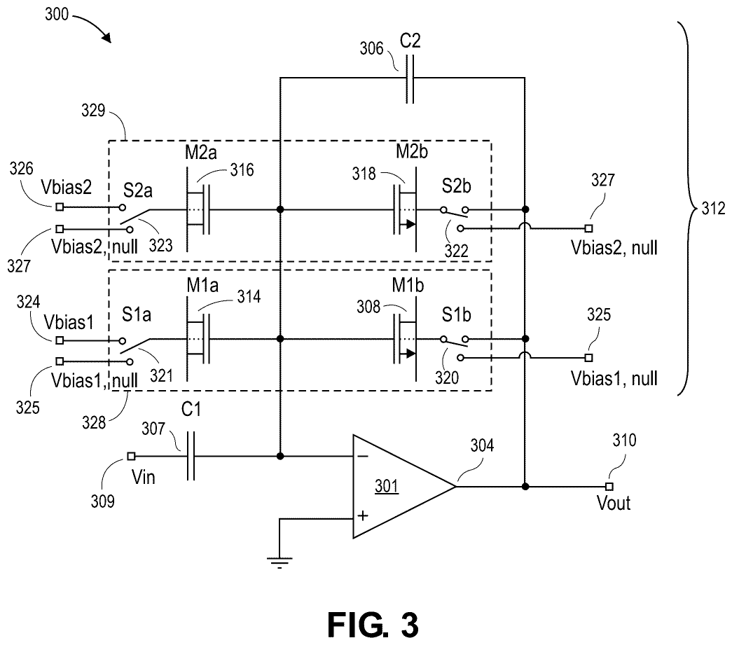

FIG. 3 is a schematic diagram of an amplifier circuit with multiple switched feedback FETs.

In circuit 300, input voltage 309 enters through capacitor 307, labeled C1, and then through core amplifier 301 to output 304 of the core amplifier. Voltage output 310 of the circuit is shared with output 304 of the core amplifier.

In feedback path 312, feedback capacitor 306, labeled C2, is shown in parallel with multiple switched FETs configured as gate tunneling resistors. FET 308, labeled M1b, is in parallel with FET 318, labeled M2b. However, they are not in the path at the same time.

Double-throw switch 320, labeled S1b, toggles between having M1b in the feedback path or to a voltage that minimizes its parasitic effects, voltage 325, labeled Vbias1,null. Similarly, double-throw switch 322, labeled S2b, toggles between having M2b in the feedback path or to a voltage that minimizes its parasitic effects, voltage 327, labeled Vbias2,null. When switch S1b is in path, switch S2b is toggled out of path and to its respective null voltage. Conversely, when switch S2b is in path, switch S1b is out of path and connects to its null voltage.

Each of these double-throw switches is paired with a corresponding double-throw switch for a corresponding bias FET. The switches in each pair operate to go in path and to a respective bias voltage, or go to a common null voltage for their respective feedback and bias FETs.

Switch S1b is paired with switch 321, labeled Sla, which toggles between providing a bias voltage to bias FET 314, labeled M1a, or to a null voltage. When S1b puts M1b in path, Sla connects M1a to bias voltage 324, labeled Vbias1. When S1b takes M1b out of path and connects it to Vbias,null, switch Sla toggles from providing Vbias1 to M1a and instead switches to null voltage 325, otherwise known as Vbias1,null. The null voltage provided to M1a and M1b are the same voltage and can be from the same supply. Either the S1a and S1b switches, or bias FET M1a and feedback FET M1b, can be referred to as pair 328.

Another pair of switches and FETs is shown as pair 329. Double-throw switch 322, labeled S2b, is closely associated with feedback gate tunneling FET 318, labeled M2b. Double-throw switch 323, labeled S2a, is closely associated with bias gate tunneling FET 316. But the two double-throw switches are associated with each other as well.

When S2b puts M2b in the feedback path, S2a connects M2a to bias voltage 326, labeled Vbias2. When S2b takes M2b out of path and connects it to Vbias,null, switch S2a toggles from providing Vbias2 to M2a and instead switches to null voltage 327, labeled Vbias2,null. Vbias2,null is also what switch S2b connects to M2b.

The null voltage Vbias, null should to be set to the desired input common-mode voltage to make sure the potential across the unused device is zero. This maximizes the resistance of the tunneling devices as mentioned above, and the leakage current is suppressed significantly due to a zero voltage difference across the tunneling devices. Otherwise, there would be residual leakage due to a mismatch in the actual input common-mode voltage and Vbias,null. This residual leakage is minimized due to the maximum tunneling leakage being biased at zero-DC. That is, there may be some electron (or hole) leakage due to random quantum tunneling, but it is not driven by electric potentials.

It can also be important to minimize the leakage of the input pairs to decouple filter AC characteristics and the core amplifier. This would be conventionally achieved by using thick-oxide devices for the input pairs. It is also common-practice to use PMOS (p-channel metal-oxide-semiconductor) for devices, which have typically less flicker noise compared to NMOS (n-channel metal-oxide-semiconductor) devices especially in thick-oxide devices. Although, common-mode range is not critical in these amplifiers, folded-cascode with PMOS input pairs can be an attractive solution. In this case, Vbias can be set to 0 V and Vbias,null can be set to one half of the common mode voltage, i.e., ½Vcm.

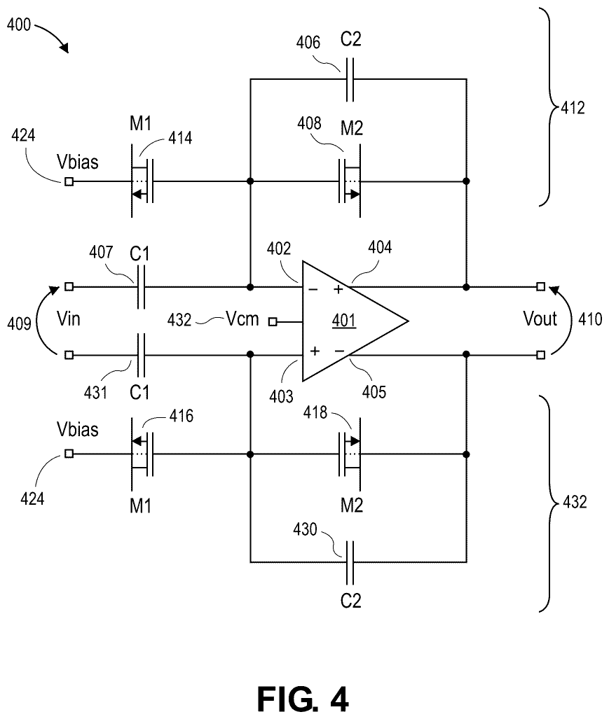

FIG. 4 is a schematic diagram of an amplifier circuit with a fully differential op amp and complementary feedback loops.

For neural electrodes in BCIs, a fully-differential op amp is preferred because fully-differential op amps have better common-mode/supply noise rejection than single ended op amps. An animal body and brain can have large common-mode noise. The common-mode noise can be suppressed significantly using fully-differential amplifiers compared to single-ended amplifiers.

In circuit 400, input voltage 409, labeled Vin, is measured between two contacts. It enters the circuit through input decoupling capacitor 407, labeled C1, and input decoupling capacitor 431, also labeled C1 because it shares the same capacitance value as capacitor 407. The output of the capacitors enters fully differential op amp 401.

Fully differential op amp 401 has differential inputs 402 and 403, which are complementary with one another. It also has differential outputs 404 and 405, which are also complementary with one another. For completeness, common mode voltage 432 is shown and labeled Vcm. The voltage between outputs 404 and 405 is the same as circuit output 410, labeled Vout.

Upper feedback loop 412 includes feedback capacitor 406, labeled C2, and feedback FET 408, labeled M2, configured for gate tunneling. Voltage bias 424, labeled Vbias, is provided through bias FET 414, labeled M1.

Lower, complementary feedback loop 432 includes feedback capacitor 430, labeled C2 because it shares the same capacitance value as capacitor 406, and feedback FET 418, labeled M2 because it shares the same characteristics as FET 408. Voltage bias 424, labeled Vbias, is also provided through bias FET 416, labeled M1 because it shares the same characteristics as FET 414.

Similar to the single ended op amp configurations, multiple feedback FETs can be placed in series within each feedback path to achieve a desired total resistance. Within each feedback loop, the multiple FET can be placed in the same or different orientations.

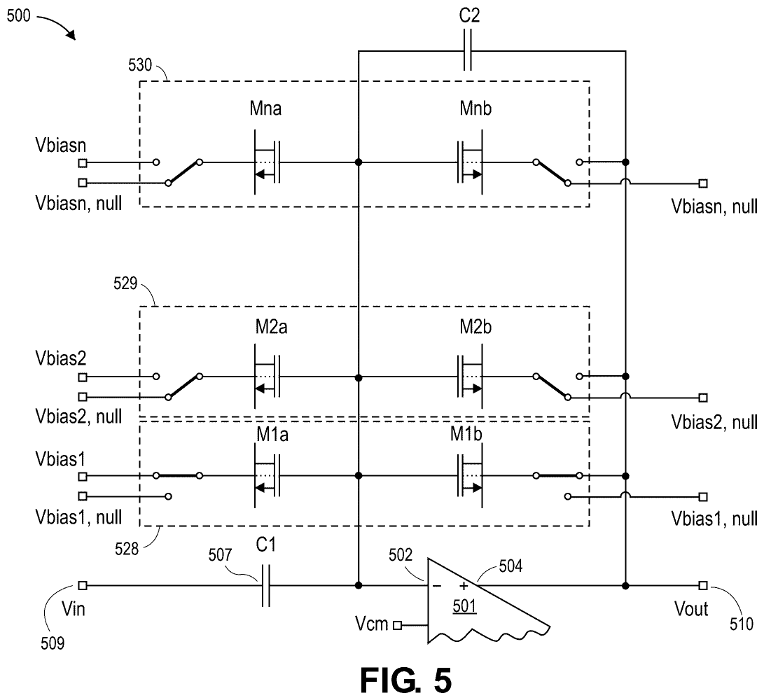

FIG. 5 is an upper half of a schematic diagram of a fully differential op amp with multiple switched feedback FETs. For conciseness, only half of the circuit (and op amp) is shown. The bottom half of the circuit is equivalent to the top half.

Input voltage 509, labeled Vin, goes across AC coupling input capacitor 507, labeled C1, to one of the differential inputs of the fully differential op amp. Differential voltage input 502 accepts signal into fully differential op amp 501, which outputs to differential output 504. Differential output 504 is coupled with output voltage 510, labeled Vout. Vout is measured across the differential outputs of fully differential op amp 501. Common mode voltage Vom is shown for completeness.

There are several switched pairs of bias and feedback FETs, similar to those in FIG. 3. Only one pair at a time is switched into the feedback path and bias. The rest are switched to their Vbias,null. For example in the figure, pair 528 is switched so that bias FET M1a provides Vbias1 to feedback FET M1b, and feedback FET M1b is switched into the feedback path. Meanwhile, all n−1 other pairs, including pair 529 and pair 530, have their bias FET Mxa's switched to provide respective Vbiasx,null to their associated feedback Mxb's, and the switches to Mxb's provide Vbiasx, null on the other side. Only M1b is in the signal path, with M1a supplying the proper bias voltage to it. The rest of the feedback and bias transistors are out of path, supplied with a null bias.

The Vbiasx voltage values may be the same for all or a subset of pairs. Similarly, the Vbiasx, null voltages may be the same for all or a subset of pairs.

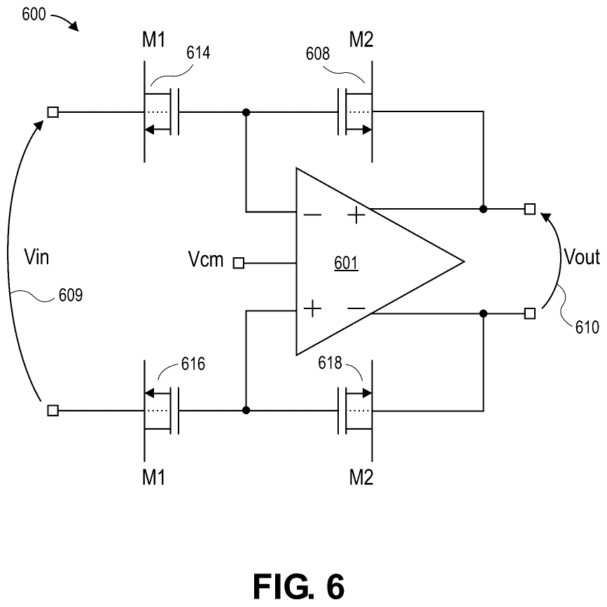

FIG. 6 is a schematic diagram of an amplifier circuit without a separate feedback capacitor. There is no separate AC coupling input capacitor either.

In circuit 600, capacitors are merged into FETs 614 and 616, both labeled M1 because they share the same characteristics. Their capacitance is used in the same way as MOS capacitors. Here, they are used for both resistive and capacitive functions.

Input to the circuit is voltage input 609, labeled Vin. Vin is provided to isolation FETs 614 and 616, which are both configured as gate tunneling resistors. Signal passes through FETs 614 and 616 to differential inputs of fully differential op amp 601.

Feedback FETs 608 and 618, both labeled M1 because they share the same characteristics, are configured as gate tunneling resistors. Feedback FET 608 is on one of the differential output paths to a differential input of the core amplifier, and feedback FET 618 is on the other of the differential output paths to the other differential input of the core amplifier. Like the M1 FETs, the M2 FETs are also used for both resistive and capacitive functions. No feedback capacitor is shown in parallel with them.

This configuration could put restrictions on the filter cutoff frequency and also introduce non-linearity; however, the real estate used is less than in other embodiments.

In the other embodiments shown, capacitors can be merged into the FETs so that no separate capacitor is required. And in other embodiments FETs can be used for their isolation capacitance.

Single-ended op amps may also be used in this configuration, whether merging the feedback capacitor into the feedback FET or using a FET for input isolation.

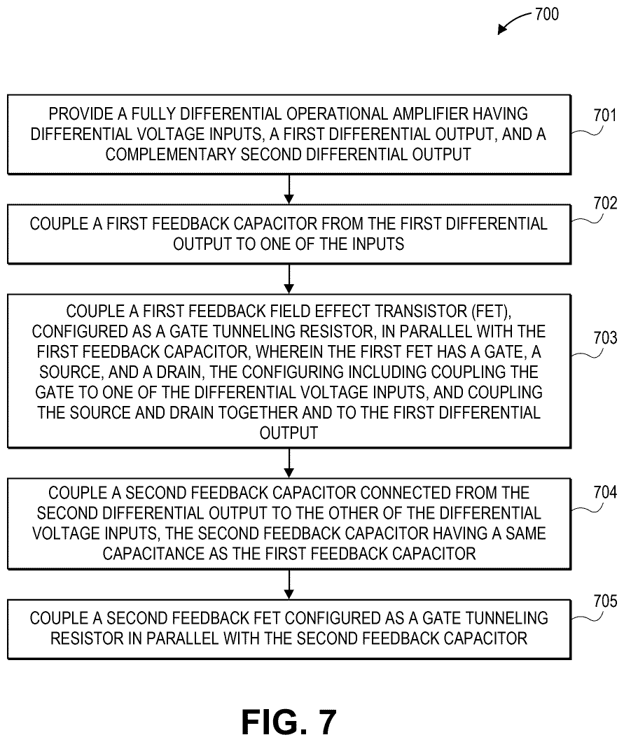

FIG. 7 is a flowchart of process 700 in accordance with an embodiment. In operation 701, a fully differential operational amplifier (op amp) having differential inputs, a first differential output, and a complementary second differential output is provided. In operation 702, a first feedback capacitor is coupled from the first differential output to one of the inputs of the op amp. In operation 703, a first feedback field effect transistor (FET), configured as a gate tunneling resistor, is coupled in parallel with the first feedback capacitor, wherein the first FET has a gate, a source, and a drain, the configuring including coupling the gate to one of the differential voltage inputs, and coupling the source and drain together and to the first differential output. The source/drain and gates can be switched around between the input and output. In operation 704, a second feedback capacitor connected from the second differential output is coupled to the other of the differential voltage inputs, the second feedback capacitor having a same capacitance as the first feedback capacitor. In operation 705, a second feedback FET configured as a gate tunneling resistor is coupled in parallel with the second feedback capacitor.

It should be appreciated that a brain implant or other system and a respective control system for the brain implant can have one or more microprocessors/processing devices that can further be a component of the overall apparatus. The control systems are generally proximate to their respective devices, in electronic communication (wired or wireless) and can also include a display interface and/or operational controls configured to be handled by a user to monitor the respective systems, to change configurations of the respective systems, and to operate, directly guide, or set programmed instructions for the respective systems, and sub-portions thereof. Such processing devices can be communicatively coupled to a non-volatile memory device via a bus. The non-volatile memory device may include any type of memory device that retains stored information when powered off. Non-limiting examples of the memory device include electrically erasable programmable read-only memory (“ROM”), flash memory, or any other type of non-volatile memory. In some aspects, at least some of the memory device can include a non-transitory medium or memory device from which the processing device can read instructions. A non-transitory computer-readable medium can include electronic, optical, magnetic, or other storage devices capable of providing the processing device with computer-readable instructions or other program code. Non-limiting examples of a non-transitory computer-readable medium include (but are not limited to) magnetic disk(s), memory chip(s), ROM, random-access memory (“RAM”), an ASIC, a configured processor, optical storage, and/or any other medium from which a computer processor can read instructions. The instructions may include processor-specific instructions generated by a compiler and/or an interpreter from code written in any suitable computer-programming language, including, for example, C, C++, C#, Java, Python, Perl, JavaScript, etc.

While the above description describes various embodiments of the invention and the best mode contemplated, regardless how detailed the above text, the invention can be practiced in many ways. Details of the system may vary considerably in its specific implementation, while still being encompassed by the present disclosure. As noted above, particular terminology used when describing certain features or aspects of the invention should not be taken to imply that the terminology is being redefined herein to be restricted to any specific characteristics, features, or aspects of the invention with which that terminology is associated. In general, the terms used in the following claims should not be construed to limit the invention to the specific examples disclosed in the specification, unless the above Detailed Description section explicitly defines such terms. Accordingly, the actual scope of the invention encompasses not only the disclosed examples, but also all equivalent ways of practicing or implementing the invention under the claims.

In some embodiments, the systems and methods of the present disclosure can be used in connection with neurosurgical techniques. However, one skilled in the art would recognize that neurosurgical techniques are a non-limiting application, and the systems and methods of the present disclosure can be used in connection with any biological tissue. Biological tissue can include, but is not limited to, the brain, muscle, liver, pancreas, spleen, kidney, bladder, intestine, heart, stomach, skin, colon, and the like.

The systems and methods of the present disclosure can be used on any suitable multicellular organism including, but not limited to, invertebrates, vertebrates, fish, birds, mammals, rodents (e.g., mice, rats), ungulates, cows, sheep, pigs, horses, non-human primates, and humans. Moreover, biological tissue can be ex vivo (e.g., tissue explant), or in vivo (e.g., the method is a surgical procedure performed on a patient).

The teachings of the invention provided herein can be applied to other systems, not necessarily the system described above. The elements and acts of the various examples described above can be combined to provide further implementations of the invention. Some alternative implementations of the invention may include not only additional elements to those implementations noted above, but also may include fewer elements. Further any specific numbers noted herein are only examples; alternative implementations may employ differing values or ranges, and can accommodate various increments and gradients of values within and at the boundaries of such ranges.

References throughout the foregoing description to features, advantages, or similar language do not imply that all of the features and advantages that may be realized with the present technology should be or are in any single embodiment of the invention. Rather, language referring to the features and advantages is understood to mean that a specific feature, advantage, or characteristic described in connection with an embodiment is included in at least one embodiment of the present technology. Thus, discussion of the features and advantages, and similar language, throughout this specification may, but do not necessarily, refer to the same embodiment. Furthermore, the described features, advantages, and characteristics of the present technology may be combined in any suitable manner in one or more embodiments. One skilled in the relevant art will recognize that the present technology can be practiced without one or more of the specific features or advantages of a particular embodiment. In other instances, additional features and advantages may be recognized in certain embodiments that may not be present in all embodiments of the present technology.

What is claimed is:

1. An integrated circuit amplifier apparatus comprising:
an operational amplifier having a voltage input and an output;
an input capacitor coupled to the voltage input;
a feedback capacitor coupled between the output and the voltage input; and
a feedback field effect transistor (FET) configured as a gate tunneling resistor in parallel with the feedback capacitor between the output and the voltage input, the FET having a gate, a source, and a drain, wherein configuring the FET as a gate tunneling resistor includes coupling the source and drain together.

2. The apparatus of claim 1 further comprising:
a bias FET configured as a gate tunneling resistor, the bias FET connected between a bias voltage source and the feedback FET.

3. The apparatus of claim 2 wherein gates of the feedback FET and the bias FET are coupled with each other.

4. The apparatus of claim 1 wherein the feedback FET is a first feedback FET, the apparatus further comprising:
a second feedback FET configured as a gate tunneling resistor in parallel with the feedback capacitor between the output and the voltage input.

5. The apparatus of claim 4 further comprising:
a first bias FET configured as a gate tunneling resistor, the first bias FET connected between a first bias voltage source and the first feedback FET;
a second bias FET configured as a gate tunneling resistor, the second bias FET connected between a second bias voltage source and the second feedback FET; and
a plurality of pairs of double-throw switches, a switch of each pair connected with one of the bias FETs and another switch of the pair connected with one of the feedback FETs, the switches of each pair configured to mutually toggle.

6. The apparatus of claim 5 wherein the first and second bias voltage sources are a same voltage source.

7. The apparatus of claim 1 further comprising:
an attenuator or feedback amplifier between the output and the feedback FET.

8. The apparatus of claim 1 wherein the feedback FET has a thickness of gate oxide of about 0.8 nanometers (nm) to about 2.2 nm, wherein the thickness enables quantum tunneling current to flow through the gate oxide from a channel beneath the gate oxide.

9. The apparatus of claim 1 wherein an equivalent resistance of the feedback FET configured as a gate tunneling resistor is greater than 1 giga-ohm (GΩ).

10. The apparatus of claim 1 wherein the feedback FET is a metal oxide field effect transistor (MOSFET).

11. An integrated circuit amplifier apparatus comprising:
a fully differential operational amplifier having differential voltage inputs, a first differential output, and a complementary second differential output;
a first feedback capacitor coupled from the first differential output to one of the inputs;
a first feedback field effect transistor (FET) configured as a gate tunneling resistor in parallel with the first feedback capacitor;
a second feedback capacitor coupled from the second differential output to the other of the differential voltage inputs, the second feedback capacitor having a same capacitance as the first feedback capacitor; and
a second feedback FET configured as a gate tunneling resistor in parallel with the second feedback capacitor.

12. The apparatus of claim 11 wherein each FET has a gate, a source, and a drain, wherein configuring each FET as a gate tunneling resistor includes coupling the source and the drain within each FET together.

13. The apparatus of claim 11 further comprising:
a first bias FET configured as a gate tunneling resistor, the first bias FET coupled between a first bias voltage source and the first feedback FET.

14. The apparatus of claim 13 further comprising:
a second bias FET configured as a gate tunneling resistor, the second bias FET coupled between the first bias voltage source and the second feedback FET.

15. The apparatus of claim 13 further comprising:
a third feedback FET configured as a gate tunneling resistor in parallel with the first feedback capacitor;
a third bias FET configured as a gate tunneling resistor, the third bias FET coupled between a second bias voltage source and the third feedback FET; and
a plurality of pairs of double-throw switches, a switch of each pair coupled with one of the bias FETs and another switch of the pair connected with one of the feedback FETs, the switches of each pair configured to mutually toggle.

16. The apparatus of claim 15 further comprising:
a fourth feedback FET configured as a gate tunneling resistor in parallel with the second feedback capacitor; and
a fourth bias FET configured as a gate tunneling resistor, the fourth bias FET coupled between the second bias voltage source and the fourth feedback FET.

17. The apparatus of claim 15 wherein the first and second bias voltage sources are a same voltage source.

18. The apparatus of claim 15 wherein a gate side of each feedback FET and a gate side of each bias FET is connected with one of the differential voltage inputs.

19. The apparatus of claim 11 further comprising:
an attenuator or feedback amplifier between the first differential output and the first feedback FET.

20. A method of manufacturing an integrated circuit amplifier, the method comprising:
providing a fully differential operational amplifier having differential voltage inputs, a first differential output, and a complementary second differential output;
coupling a first feedback capacitor from the first differential output to one of the inputs;
coupling a first feedback field effect transistor (FET), configured as a gate tunneling resistor, in parallel with the first feedback capacitor, wherein the first FET has a gate, a source, and a drain, the configuring including coupling the gate to one of the differential voltage inputs, and coupling the source and the drain together and to the first differential output;
coupling a second feedback capacitor connected from the second differential output to the other of the differential voltage inputs, the second feedback capacitor having a same capacitance as the first feedback capacitor; and
coupling a second feedback FET configured as a gate tunneling resistor in parallel with the second feedback capacitor.
